(19) United States
(12) Patent Application Publication
(10) Pub. No.: US 2025/0386736 A1
(43) Pub. Date: Dec. 18, 2025

(54) METHOD OF FORMING THIN FILM OF MAGNETIC TUNNEL JUNCTION, METHOD OF MANUFACTURING MEMORY DEVICE USING THE SAME, AND MEMORY DEVICE THEREBY

(71) Applicants: SAMSUNG ELECTRONICS CO., LTD., Suwon-si (KR); Seoul National University R&DB Foundation, Seoul (KR)

(72) Inventors: Won Joon CHO, Suwon-si (KR); Yun Seog Lee, Seoul (KR); Ki Tae Park, Seoul (KR); Young Ho Chu, Seoul (KR); Jae Hong Lee, Suwon-si (KR); Hyeongseok JANG, Suwon-si (KR); Jaewon Kim, Suwon-si (KR); Taehoon Kim, Suwon-si (KR); Hyungjun Youn, Suwon-si (KR); Woochang LEE, Suwon-si (KR)

(21) Appl. No.: 19/232,191

(22) Filed: Jun. 9, 2025

(30) Foreign Application Priority Data
Jun. 13, 2024 (KR) 10-2024-0077019

(51) Int. Cl. H10N 50/01; H10B 61/00; H10N 50/10; H10N 50/85

(52) U.S. Cl. CPC H10N 50/01; H10B 61/20; H10N 50/10; H10N 50/85

(57) ABSTRACT

A topological material thin film is formed by forming an adhesive layer on a surface of a topological material bulk, forming a stress source layer on a surface of the adhesive layer, attaching an auxiliary substrate onto a surface of the stress source layer, and applying a physical force to the auxiliary substrate to separate the auxiliary substrate from the topological material bulk, and a memory device is formed by bonding the topological material thin film to a separately formed magnetic tunnel junction structure.

### CROSS-REFERENCE TO RELATED APPLICATION

This application claims priority to Korean Patent Application No. 10-2024-0077019, filed on Jun. 13, 2024, and all the benefits accruing therefrom under 35 U.S.C. § 119, the content of which in its entirety is herein incorporated by reference.

### BACKGROUND

### (a) Field

The present disclosure relates to a method of forming a thin film of a topological material, a method of manufacturing a memory device using the method, and a memory device manufactured thereby.

### (b) Description of the Related Art

Non-volatile memory devices using the tunnel magnetoresistance effect are being developed. Such non-volatile memory devices include a spin transfer torque-magnetoresistive random access memory (STT-MRAM), which uses spin transfer torque, and a spin orbit torque-magnetoresistive random access memory (SOT-MRAM), which uses spin orbital torque. Among them, SOT-MRAM has desired characteristics of no interference when reading data, faster switching operation, and lower current for magnetization reversal.

### SUMMARY

To manufacture a spin orbit torque-magnetoresistive random access memory (SOT-MRAM), a topological material thin film may be desirable to be formed and combined with a magnetic tunnel junction (MTJ) structure to be patterned into the desired shape, but it may be difficult to form the topological thin film because thin films may not be formed well due to differences in lattice constant and surface energy, and the formed thin films may be deteriorated due to the process environment.

An embodiment of the present disclosure provides a method of forming a topological material thin film.

An embodiment of the present disclosure is directed to forming a topological material thin film, combining the topological material with a magnetic tunnel junction structure to manufacture a SOT-MRAM.

An embodiment provides a method of forming a thin film of a magnetic tunnel junction structure, including: forming a magnetic tunnel junction structure on a temporary substrate by stacking a free layer, a tunneling layer, and a fixed layer on the temporary substrate; forming a capping layer on the magnetic tunnel junction structure; forming an adhesive layer on the capping layer; forming a stress source layer on the adhesive layer; attaching an auxiliary substrate onto a surface of the stress source layer; and separating the magnetic tunnel junction structure from the temporary substrate by applying a physical force to the auxiliary substrate, wherein a separation state of the magnetic tunnel junction structure from the auxiliary substrate is controlled, by controlling at least one selected from a thickness and a formation process condition of the stress source layer.

In an embodiment, the stress source layer may be formed by sputtering metal.

In an embodiment, the stress source layer may include nickel and may be formed to have a thickness in a range of about 20 nanometers (nm) to about 3000 nm.

In an embodiment, an internal temperature of a sputtering chamber may be in a range of about 90° C. to about 200° C. when the stress source layer is formed.

In an embodiment, the adhesive layer may include titanium, and the adhesive layer may have a thickness in a range of about 5 nm to about 50 nm.

In an embodiment, the adhesive layer may be formed by thermal evaporation deposition of titanium.

Another embodiment provides a method of manufacturing a memory device, including: sequentially forming a first adhesive layer and a first stress layer on a surface of a topological material bulk; attaching a first auxiliary substrate onto a surface of the first stress source layer and applying a physical force to the first auxiliary substrate to separate a topological material thin film from the topological material bulk; forming a magnetic tunnel junction structure including a free layer, a tunneling layer, and a fixed layer on a temporary substrate, and forming a capping layer on the magnetic tunnel junction structure; sequentially forming a second adhesive layer and a second stress source layer on the capping layer; attaching a second auxiliary substrate onto a surface of the second stress source layer and applying a physical force to the second auxiliary substrate to separate the magnetic tunnel junction structure from the temporary substrate; bonding the topological material thin film onto the first auxiliary substrate and bonding the magnetic tunnel junction structure onto the second auxiliary substrate; separating the first stress source layer and the first adhesive layer together with the first auxiliary substrate from the topological material thin film; and bonding a device substrate onto the topological material thin film, and separating the second stress source layer, the second adhesive layer, and the capping layer together with the second auxiliary substrate from the magnetic tunnel junction structure.

In an embodiment, the method of manufacturing the memory device may further include patterning the topological material thin film and the magnetic tunnel junction structure on the device substrate and forming a wiring.

In an embodiment, the topological material thin film may include at least one selected from WTe₂, BiₓSe₁₋ₓSb_{y}Te_{1-y} (BSTS), Bi₂Te₂Se (BTS), Bi₂Se₂Te (BST), EuMnBi₂, WTe₂, ZrTe₅, and SrRuO₃.

In an embodiment, the topological material thin film may be a perovskite with an ABO₃ crystal structure, where A is an alkaline earth metal cation, and B is a transition metal cation.

In an embodiment, each of the first and second adhesive layers may include titanium, and each of the first and second adhesive layers may have a thickness in a range of about 5 nm to about 50 nm.

In an embodiment, the first and second stress source layers may include nickel, and each of the first and second stress source layers may have a thickness in a range of about 20 nm to about 3000 nm.

In an embodiment, the adhesive layer may be formed by thermal evaporation deposition of titanium, and the stress source layer may be formed by sputtering nickel at a temperature in a range of about 90° C. to about 200° C.

In an embodiment, the first and second auxiliary substrates may be adhesive tapes.

In an embodiment, the device substrate may include a transistor and a wiring.

Another embodiment provides a memory device including: a topological material layer; a magnetic tunnel junction structure disposed on the topological material layer, where the magnetic tunnel junction structure includes a free layer, a tunneling layer, and a fixed layer; a first wiring and a second wiring connected to opposing sides of a lower surface of the topological material layer, respectively; a third wiring connected to an upper surface of the fixed layer of the magnetic tunnel junction structure; and a switching transistor connected to the first wiring, where spin Hall angle is in a range of about 10 and about 1,000,000.

In an embodiment, the topological material layer includes at least one selected from WTe₂, BiₓSe₁₋ₓSb_{y}Te_{1-y} (BSTS), Bi₂Te₂Se (BTS), Bi_{z}Se₂Te (BST), EuMnBi₂, WTe₂, ZrTe₅, and SrRuO₃.

In an embodiment, the topological material layer may be a perovskite with an ABO₃ crystal structure, where A is an alkaline earth metal cation, and B is a transition metal cation.

In an embodiment, the free layer and the fixed layer may be ferromagnetic materials, and the tunneling layer may be an insulating film.

In an embodiment, the tunneling layer may include at least one selected from oxides of magnesium (Mg), titanium (Ti), aluminum (Al), magnesium-zinc (MgZn) and magnesium-boron (MgB), and nitrides of titanium (Ti) and vanadium (V).

According to embodiments, a topological material thin film may be formed by peeling off a lump of topological material using a stress source layer. According to embodiments, an SOT-MRAM may be manufactured by combining a topological material thin film with a magnetic tunnel junction structure.

### BRIEF DESCRIPTION OF THE DRAWINGS

FIG. 1 illustrates a perspective view of a spin orbit torque-magnetoresistive random access memory (SOT-MRAM) manufactured through a method of manufacturing a memory device by separating a thin film of a topological material according to an embodiment.

FIG. 2 and FIG. 3 illustrate cross-sectional views of intermediate steps in a process for separating a topological material thin film according to an embodiment.

FIG. 4 to FIG. 6 illustrate cross-sectional views of intermediate steps in a process for preparing a magnetic tunnel junction structure according to an embodiment.

FIG. 7 and FIG. 8 illustrate cross-sectional views of intermediate steps in a process for combining a topological material thin film with a magnetic tunnel junction structure according to an embodiment.

FIG. 9 illustrates a cross-sectional view of a process for bonding a device substrate to a combination of a topological material thin film and a magnetic tunnel junction structure according to an embodiment.

FIG. 10 illustrates a cross-sectional view of a memory device manufactured by patterning a combination of a topological material thin film bonded to a device substrate and a magnetic tunnel junction structure according to an embodiment.

FIG. 11 illustrates a flowchart of a method of manufacturing a memory device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The drawings and the descriptions are merely illustrative and not considered as restrictive. Throughout the specification, the same reference numbers indicate the same constituent elements.

In the drawings, the size and thickness of each constituent element may be arbitrarily shown for better understanding and ease of description, and the present disclosure is not necessarily limited to what is shown in the drawings. In the drawings, the thickness of layers, films, plates, regions, areas, and the like may be exaggerated for clarity. In the drawings, the thickness of some layers, areas, and regions may be exaggerated for better understanding and ease of description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the specification and the claims, the phrase “at least one of” is intended to include the meaning of “at least one selected from” for the purpose of its meaning and interpretation. For example, “at least one of A and B” may be understood to mean “A, B, or A and B.”

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

When an element, such as a layer, a film, a region, an area, or a substrate is described to be “above” another element, it may be directly above another element or there may be an intermediate element. In contrast, when a first element is described to be “directly above” a second element, there is no intermediate element. Throughout the specification, the term “above” a target must be “understood as being disposed above or below the target element, and does not necessarily signify “above” with respect to an opposite direction of gravity.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

When an element (or region, area, layer, portion, etc.) is described to be “connected” or “combined” to another element in the specification, it may be directly disposed, connected, or combined on the above-noted other element, or an element may be disposed therebetween.

The term “connected to” or “combined to” may include physical or electrical connections or combinations.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

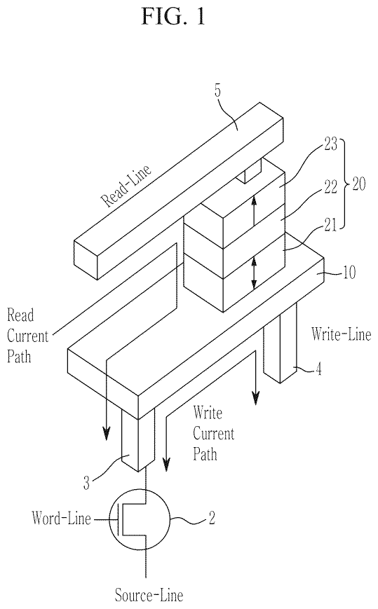

FIG. 1 illustrates a perspective view of a spin orbit torque-magnetoresistive random access memory (SOT-MRAM) manufactured through a method of manufacturing a memory device using a method of separating a thin film of a topological material according to an embodiment.

A memory device manufactured using a method of separating a thin film of a topological material according to an embodiment may have a structure in which wirings 3, 4, and 5 and a switching transistor 2 for performing write and read are connected to a structure in which a topological material layer 10 and a magnetic tunnel junction structure 20 are bonded to each other. The first and second wirings 3 and 4 may be connected to both opposing sides of a lower surface of the topological material layer 10, and the third wiring 5 may be connected to an upper surface of a fixed layer 23 of the magnetic tunnel junction structure 20. The switching transistor 2 may be connected to the first wiring 3. That is, the first wiring 3 may connect the switching transistor 2 and the topological material layer 10. In an embodiment, the memory device may be a magnetoresistive random access memory (MRAM).

The topological material layer 10 is a material that may induce a resistance change in MRAM and may include or be made of a material synthesized through a single crystal growth method. In an embodiment, for example, the topological material layer 10 may include or be made of at least one selected from WTe₂, BiₓSe₁₋ₓSb_{y}Te_{1-y} (BSTS), Bi₂Te₂Se (BTS), Bi_{z}Se₂Te (BST), EuMnBi₂, WTe₂, ZrTe₅, and SrRuO₃. The thickness of the topological material layer 10 may be in a range of about 1 nanometer (nm) to about 100 nm, e.g., in a range of about 10 nm to about 30 nm.

In an embodiment, the topological material layer 10 may be perovskite with an ABO₃ crystal structure. In the chemical formula ABO₃ of perovskite, A may be a metal cation such as an alkaline earth metal cation (Sr²⁺ or Ba²⁺), and B may be a transition metal cation. The crystal structure of perovskite is a BO₆ octahedron with shared corners in a three-dimensional arrangement, and in this case, the space between the oxygen octahedrons may be occupied by A cations. In an embodiment of the perovskite of the present disclosure, the constituent blocks of the BO₆ octahedra may have oxygen octahedral connectivity that is inclined toward an ideal equiaxed structure.

Transition metal oxides are free from oxidation problems that may inevitably appear in the process of miniaturization/integration of devices, and complex oxides have desired characteristics of having various new quantum states due to interactions between multiple degrees of freedom (lattice, charge, spin, orbital). In addition, various physical properties/functionalities that do not exist in nature have already been realized through the ABO₃ perovskite oxide.

In an embodiment, the topological material layer 10 may be peeled from a single crystal grown bulk and combined with a separately formed magnetic tunnel junction structure 20 to produce a large spin Hall effect. The spin Hall angle of the magnetic memory device according to an embodiment may be a value in a range of about 10 and about 1,000,000, which is more than 10 times higher than that of a case in which the topological material layer 10 and the magnetic tunnel junction structure 20 are formed by sequentially stacking one on another through a method such as deposition.

The magnetic tunnel junction structure 20 may include a free layer 21, a tunneling layer (or barrier layer) 22, and a fixed layer 23. The free layer 21 and the fixed layer 23 may be ferromagnetic material layers, and the tunneling layer 22 may be an insulating film. The free layer 21 and the fixed layer 23 may include or be made of various ferromagnetic materials depending on desired characteristics.

The tunneling layer 22 may include at least one selected from oxides of magnesium (Mg), titanium (Ti), aluminum (Al), magnesium-zinc (MgZn), and magnesium-boron (MgB), and nitrides of titanium (Ti) and vanadium (V). In an embodiment, for example, the tunneling layer 22 may be a magnesium oxide (MgO) film.

The magnetization of the fixed layer 23 may be fixed. As magnetization switching occurs in the free layer 21, the magnetization vector of the fixed layer 23 may be parallel or anti-parallel to the magnetization vector of the free layer 21. When the magnetization vectors of the free layer 21 and the fixed layer 23 are parallel with each other, the resistance of the magnetic memory device may be measured relatively small due to a large tunneling effect occurring in the tunneling layer 22 disposed between the free layer 21 and the fixed layer 23. When the magnetization vectors of the free layer 21 and the fixed layer 23 are anti-parallel with each other, the resistance of the magnetic memory device may be measured relatively large due to a small tunneling effect occurring in the tunneling layer 22 disposed between the free layer 21 and the fixed layer 23. The change in the resistance of the magnetic memory device depending on the direction of the magnetization vector of the free layer 21 and the fixed layer 23 is due to the spin polarization of the free layer 21 and the fixed layer 23, which are ferromagnetic, and the tunneling effect of electrons passing through the tunneling layer 22. The relatively small and large resistance of the magnetic memory device may correspond to logic 0 and logic 1, respectively.

The fixed layer 23 may include Fe, Co, Ni, or an alloy thereof, which are ferromagnetic materials, or may have a multilayer structure thereof. In addition, the fixed layer 23 may further include B, Cr, Pt, Pd, or the like. In an embodiment, for example, the fixed layer 23 may include NiFe, CoFe, NiFeB, CoFeB, NiFeSiB, or CoFeSiB.

When the magnetic memory device performs a write operation, an inclined spin current is generated in the free layer 21 by a spin-Hall effect generated by the charging current supplied through the free layer 21, and the net magnetization vector of the free layer 21 may be switched. The state of the switched magnetization vector may correspond to the recording of data.

When the magnetic memory device performs a read operation, the resistance of the magnetic memory device may be measured by a resistance measuring device. The measurement of the resistance may be performed by a sensing voltage generated by transmitting a small sensing current to the magnetic memory device. A value corresponding to the measured resistance may be outputted as a result of the read operation. Generally, when the magnetization vector of the free layer 21 and the magnetization vector of the fixed layer 23 are aligned in parallel with each other, the resistance of the magnetic memory device may be measured as a relatively small value.

The switching transistor 2 and the wirings 3 and 4 may be implemented by a method such as doping, deposition, or photo etching on a semiconductor substrate such as silicon, and the topological material layer 10 and the magnetic tunnel junction structure 20 may be defined by a structure patterned after being transferred onto a semiconductor substrate on which the switching transistor 2 and the wirings 3 and 4 are formed. Some wiring 5 may be formed after forming the structure of the topological material layer 10 and the magnetic tunnel junction structure 20.

In another embodiment, the switching transistor 2 and the wirings 3, 4, and 5 may be formed after transferring and patterning the topological material layer 10 and the magnetic tunnel junction structure 20 on a semiconductor substrate to form the structure of the topological material layer 10 and the magnetic tunnel junction structure 20.

A method of manufacturing a memory device according to an embodiment hereinafter will be described in detail.

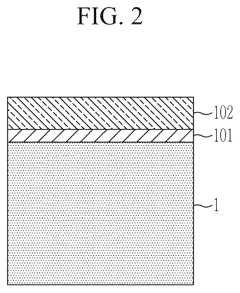

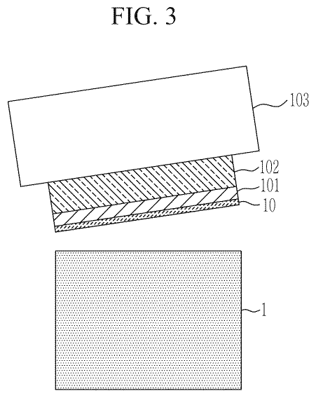

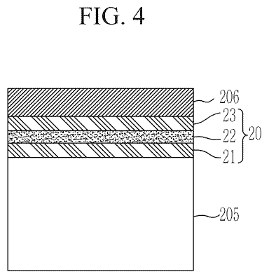

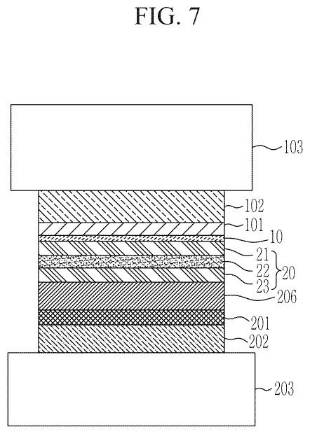

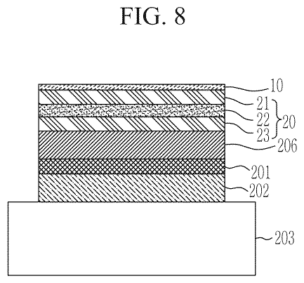

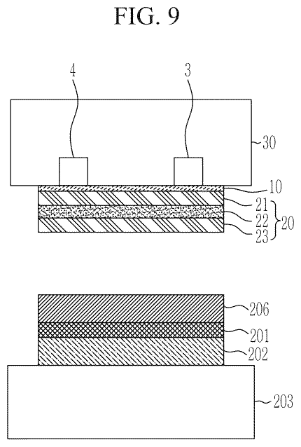

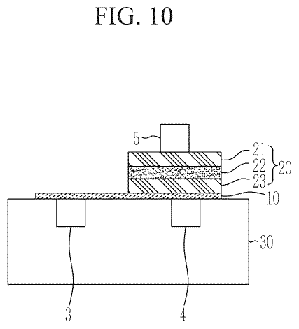

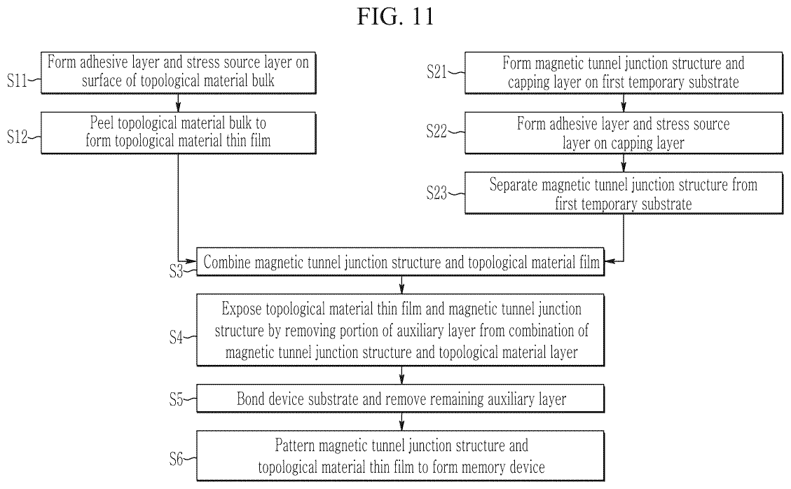

FIG. 2 and FIG. 3 illustrate cross-sectional views of intermediate steps in a process for separating a topological material thin film according to an embodiment. FIG. 4 to FIG. 6 illustrate cross-sectional views of intermediate steps in a process for preparing a magnetic tunnel junction structure according to an embodiment. FIG. 7 and FIG. 8 illustrate cross-sectional views of intermediate steps in a process for combining a topological material thin film with a magnetic tunnel junction structure according to an embodiment. FIG. 9 illustrates a cross-sectional view of a process for bonding a device substrate to a combination of a topological material thin film and a magnetic tunnel junction structure according to an embodiment. FIG. 10 illustrates a cross-sectional view of a memory device manufactured by patterning a combination of a topological material thin film bonded to a device substrate and a magnetic tunnel junction structure according to an embodiment. FIG. 11 illustrates a flowchart of a method of manufacturing a memory device according to an embodiment.

Referring to FIG. 2 and FIG. 11, in an embodiment of a method of manufacturing a memory device, an adhesive layer 101 and a stress source layer 102 may be deposited on a surface of a topological material bulk 1 synthesized through a single crystal growth method (S11). The topological material bulk 1 may include at least one selected from WTe₂, BiₓSe₁₋ₓSb_{y}Te_{1-y} (BSTS), Bi₂Te₂Se (BTS), Bi_{z}Se₂Te (BST), EuMnBi₂, WTe₂, ZrTe₅, and SrRuO₃. The adhesive layer 101 may be formed by thermal evaporation of titanium (Ti) and may be formed to have a thickness in a range of about 5 nm to about 50 nm. The stress source layer 102 may be formed by sputtering nickel (Ni), and can be formed by adjusting the thickness to be in a range of about 20 nm to about 3000 nm. The stress source layer 102 may serve to peeling the surface portion of the topological material bulk 1 by providing stress to the surface of the topological material bulk 1 through the adhesive layer 101. When the stress source layer 102 is formed, the magnitude of the stress provided by the stress source layer 102 may be controlled by controlling the internal pressure condition and temperature of the sputtering chamber and the thickness of the stress source layer 102. The internal temperature of the sputtering chamber may be in a range of about 90° C. and about 200° C.

Next, referring to FIG. 3 and FIG. 11, a first auxiliary substrate 103 is attached on the stress source layer 102 and separated from topological material bulk 1 by applying physical force, such that the surface portion of the topological material bulk 1 may be peeled off and separated from the topological material bulk 1 in a state of being attached to the adhesive layer 101, thereby forming the topological material layer 10 (S12). In an embodiment, the first auxiliary substrate 103 may be an adhesive tape with an adhesive applied to a surface thereof.

Referring to FIG. 4 and FIG. 11, in an embodiment of a method of manufacturing a memory device, the free layer 21, the tunneling layer 22, and the fixed layer 23 may be sequentially stacked on a temporary substrate 205 to form a magnetic tunnel junction structure 20, and a capping layer 206 may be formed on the magnetic tunnel junction structure 20 (S21). The free layer 21, the tunneling layer 22, and the fixed layer 23 may be formed through a method such as sputtering, thermal evaporation deposition, or the like, and the fixed layer 23 may include a plurality of layers. The temporary substrate 205 may include at least one selected from glass, silicon, and polymer, and may further include one or more auxiliary layers formed on the substrate.

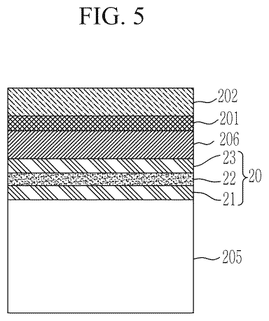

Referring to FIG. 5 and FIG. 11, in an embodiment of a method of manufacturing a memory device, an adhesive layer 201 and a stress source layer 202 may be formed on the capping layer 206 (S22). The adhesive layer 201 may be formed by thermal evaporation of titanium (Ti) and may be formed to have a thickness in a range of about 5 nm to about 50 nm. The stress source layer 202 may be formed by sputtering nickel (Ni), and can be formed by adjusting the thickness to be in a range of about 20 nm to about 3000 nm. The stress source layer 202 may serve to separate the capping layer 206 from the magnetic tunnel junction structure 20 by providing stress to the capping layer 206 through the adhesive layer 201. In addition, the stress source layer 202 may serve to separate the magnetic tunnel junction structure 20 from the temporary substrate 205 by providing stress to the magnetic tunnel junction structure 20. When the stress source layer 202 is formed, the magnitude of the stress provided by the stress source layer 202 may be controlled by controlling the internal pressure condition and temperature of the sputtering chamber and the thickness of the stress source layer 202. The internal temperature of the sputtering chamber may be in a range of about 90° C. and about 200° C.

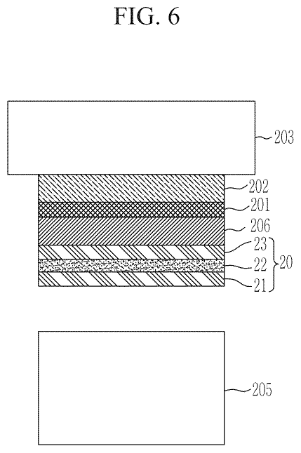

Referring to FIG. 6 and FIG. 11, in an embodiment of a method of manufacturing a memory device, a second auxiliary substrate 203 is attached onto the stress source layer 202 and a physical force is applied thereto, such that the temporary substrate 205 may be separated from the magnetic tunnel junction structure 20 (S23). Accordingly, the free layer 21 of the magnetic tunnel junction structure 20 may be exposed. In an embodiment, the second auxiliary substrate 203 may be an adhesive tape with an adhesive applied to a surface thereof.

Referring to FIG. 7 and FIG. 11, in an embodiment of a method of manufacturing a memory device, the topological material layer 10 attached onto the first auxiliary substrate 103 may be coupled onto the free layer 21 of the magnetic tunnel junction structure 20 attached to the second auxiliary substrate 203 (S3).

Referring to FIG. 8 and FIG. 11, in an embodiment of a method of manufacturing a memory device, the stress source layer 102 and the adhesive layer 101 together with the first auxiliary substrate 103 may be separated from the topological material layer 10 (S4). In this process, a partial thickness portion of the topological material layer 10 may be attached to the adhesive layer 101 and separated from the topological material layer 10.

In another embodiment, instead of separating the stress source layer 102 and the adhesive layer 101 from the topological material layer 10 together with the first auxiliary substrate 103, the stress source layer 202, the adhesive layer 201, and the capping layer 206 may be separated from the magnetic tunnel junction structure 20 together with the second auxiliary substrate 203.

Next, referring to FIG. 9 and FIG. 11, in an embodiment of a method of manufacturing a memory device, a device substrate 30 may be bonded on the topological material layer 10, and the stress source layer 202, the adhesive layer 201, and the capping layer 206 may be separated from the magnetic tunnel junction structure 20 together with the second auxiliary substrate 203 (S5). The device substrate 30 may include the wirings 3 and 4 and a transistor device.

In another embodiment, the device substrate 30 may be bonded to the fixed layer 23 of the magnetic tunnel junction structure 20, and the stress source layer 102 and the adhesive layer 101 may be separated from the topological material layer 10 together with the first auxiliary substrate 103.

Referring to FIG. 10 and FIG. 11, in an embodiment of a method of manufacturing a memory device, the topological material layer 10 and the magnetic tunnel junction structure 20 bonded to the device substrate 30 may be patterned to have a predetermined shape by a method such as photo etching, and an additional configuration such as the wiring 5 may be formed thereon using methods such as film deposition and photo etching, thereby manufacturing a memory device (S6).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of forming a thin film of a magnetic tunnel junction structure, the method comprising:
forming a magnetic tunnel junction structure on a temporary substrate by stacking a free layer, a tunneling layer, and a fixed layer on the temporary substrate;
forming a capping layer on the magnetic tunnel junction structure;
forming an adhesive layer on the capping layer;
forming a stress source layer on the adhesive layer;
attaching an auxiliary substrate onto a surface of the stress source layer; and
separating the magnetic tunnel junction structure from the temporary substrate by applying a physical force to the auxiliary substrate,
wherein a separation state of the magnetic tunnel junction structure from the auxiliary substrate is controlled, by controlling at least one selected from a thickness and a formation process condition of the stress source layer.

2. The method of forming the thin film of the magnetic tunnel junction structure of claim 1, wherein
the stress source layer is formed by sputtering metal.

3. The method of forming the thin film of the magnetic tunnel junction structure of claim 2, wherein
the stress source layer includes nickel, and
the stress source layer has a thickness in a range of about 20 nm to about 3000 nm.

4. The method of forming the thin film of the magnetic tunnel junction structure of claim 3, wherein
an internal temperature of a sputtering chamber is in a range of about 90° C. to about 200° C. when the stress source layer is formed.

5. The method of forming the thin film of the magnetic tunnel junction structure of claim 4, wherein
the adhesive layer includes titanium, and
the adhesive layer has a thickness in a range of about 5 nm to about 50 nm.

6. The method of forming the thin film of the magnetic tunnel junction structure of claim 5, wherein
the adhesive layer is formed by thermal evaporation deposition of titanium.

7. A method of manufacturing a memory device, the method comprising:
sequentially forming a first adhesive layer and a first stress layer on a surface of a topological material bulk;
attaching a first auxiliary substrate onto a surface of the first stress source layer and applying a physical force to the first auxiliary substrate to separate a topological material thin film from the topological material bulk;
forming a magnetic tunnel junction structure including a free layer, a tunneling layer, and a fixed layer on a temporary substrate, and forming a capping layer on the magnetic tunnel junction structure;
sequentially forming a second adhesive layer and a second stress source layer on the capping layer;
attaching a second auxiliary substrate onto a surface of the second stress source layer and applying a physical force to the second auxiliary substrate to separate the magnetic tunnel junction structure from the temporary substrate;
bonding the topological material thin film onto the first auxiliary substrate and bonding the magnetic tunnel junction structure onto the second auxiliary substrate;
separating the first stress source layer and the first adhesive layer together with the first auxiliary substrate from the topological material thin film; and
bonding a device substrate onto the topological material thin film, and separating the second stress source layer, the second adhesive layer, and the capping layer together with the second auxiliary substrate from the magnetic tunnel junction structure.

8. The method of manufacturing the memory device of claim 7, further comprising
patterning the topological material thin film and the magnetic tunnel junction structure on the device substrate and forming a wiring.

9. The method of manufacturing the memory device of claim 8, wherein
the topological material thin film includes at least one selected from WTe₂, BiₓSe₁₋ₓSb_{y}Te_{1-y} (BSTS), Bi₂Te₂Se (BTS), Bi_{z}Se₂Te (BST), EuMnBi₂, WTe₂, ZrTe₅, and SrRuO₃.

10. The method of manufacturing the memory device of claim 8, wherein
the topological material thin film is a perovskite with an ABO₃ crystal structure,
wherein A is an alkaline earth metal cation, and B is a transition metal cation.

11. The method of manufacturing the memory device of claim 7, wherein
each of the first and second adhesive layers includes titanium, and
each of the first and second adhesive layers has a thickness in a range of about 5 nm to about 50 nm.

12. The method of manufacturing the memory device of claim 11,
wherein
each of the first and second stress source layers includes nickel, and
each of the first and second stress source layers has a thickness in a range of about 20 nm to about 3000 nm.

13. The method of manufacturing the memory device of claim 12, wherein
the adhesive layer is formed by thermal evaporation deposition of titanium, and
the stress source layer is formed by sputtering nickel at a temperature in a range of about 90° C. to about 200° C.

14. The method of manufacturing the memory device of claim 7,
wherein the first and second auxiliary substrates are adhesive tapes.

15. The method of manufacturing the memory device of claim 8, wherein
the device substrate includes a transistor and a wiring.

16. A memory device comprising:
a topological material layer;
a magnetic tunnel junction structure disposed on the topological material layer, wherein the magnetic tunnel junction structure includes a free layer, a tunneling layer, and a fixed layer;
a first wiring and a second wiring connected to opposing sides of a lower surface of the topological material layer, respectively;
a third wiring connected to an upper surface of the fixed layer of the magnetic tunnel junction structure; and
a switching transistor connected to the first wiring,
wherein spin Hall angle is in a range of about 10 and about 1,000,000.

17. The memory device of claim 16, wherein
the topological material layer includes at least one selected from WTe₂, BiₓSe₁₋ₓSb_{y}Te_{1-y} (BSTS), Bi₂Te₂Se (BTS), Bi_{z}Se₂Te (BST), EuMnBi₂, WTe₂, ZrTe₅, and SrRuO₃.

18. The memory device of claim 16, wherein
the topological material layer is a perovskite with an ABO₃ crystal structure,
wherein A is an alkaline earth metal cation, and B is a transition metal cation.

19. The memory device of claim 16, wherein
the free layer and the fixed layer are ferromagnetic materials, and
the tunneling layer is an insulating film.

20. The memory device of claim 19, wherein
the tunneling layer includes at least one selected from oxides of magnesium (Mg), titanium (Ti), aluminum (Al), magnesium-zinc (MgZn) and magnesium-boron (MgB), and nitrides of titanium (Ti) and vanadium (V).
